(19) United States
(12) Patent Application Publication
(10) Pub. No.: US 2025/0204112 A1
(43) Pub. Date: Jun. 19, 2025

(54) LIGHT-EMITTING DEVICE, INORGANIC MEMBER, AND MANUFACTURING METHOD FOR LIGHT-EMITTING DEVICE

(71) Applicant: NICHIA CORPORATION, Anan-shi (JP)

(72) Inventor: Kaisei EGUCHI, Tokushima-shi (JP)

(73) Assignee: NICHIA CORPORATION, Anan-shi (JP)

(21) Appl. No.: 18/985,470

(22) Filed: Dec. 18, 2024

(30) Foreign Application Priority Data
Dec. 19, 2023 (JP) 2023-213899

(51) Int. Cl. H10H 20/856; H10H 20/01

(52) U.S. Cl. CPC H10H 20/856; H10H 20/0363

(57) ABSTRACT

A light-emitting device includes a light-emitting element, and a light-reflective member that includes an inorganic member and reflects light from the light-emitting element. The inorganic member contains silicon oxide, an alkali metal, and a hydroxide containing an alkaline earth metal.

### CROSS-REFERENCE TO RELATED APPLICATIONS

The present application claims priority under 35 U.S.C. § 119 to Japanese Patent Application No. 2023-213899, filed Dec. 19, 2023, the disclosure of which is hereby incorporated by reference in its entirety.

### BACKGROUND

### 1. Technical Field

The present disclosure relates to a light-emitting device, an inorganic member, and a manufacturing method for the light-emitting device.

### 2. Description of Related Art

Japanese Patent Publication No. 2014-216416 discloses a light-emitting device including a light-emitting element such as an LED, and a covering member that has light reflectivity and covers a part of the light-emitting element. Japanese Patent Publication No. 2014-216416 discloses, as the covering member having light reflectivity, a base material formed of a heat-resistant resin such as silicone resin or of an inorganic binder and containing a reflective material that contains a white pigment such as titanium oxide, zinc oxide, tantalum oxide, niobium oxide, zirconium oxide, or aluminum oxide, or combinations thereof.

### SUMMARY

However, such a covering member having light reflectivity and containing an inorganic binder (hereinafter referred to as a light-reflective member) still has room for improvement. For example, when a covering member covering a light-emitting element is irradiated with light from the light-emitting element, heat is generated. Thus, further improvement in the heat dissipation properties of the covering member is required.

Thus, an object of the present disclosure is to provide a light-emitting device including a light-reflective member having light reflectivity and high heat dissipation properties, an inorganic member that can improve the performance of the light-reflective member, and a manufacturing method for the light-emitting device including the light-reflective member having high heat dissipation properties.

A light-emitting device according to the present disclosure includes a light-emitting element, and a light-reflective member including an inorganic member and configured to reflect light emitted from the light-emitting element. The inorganic member contains silicon oxide, an alkali metal, and a hydroxide containing an alkaline earth metal.

An inorganic member according to one aspect of the present disclosure contains silicon oxide, an alkali metal, and a hydroxide containing an alkaline earth metal.

An inorganic member according to another aspect of the present disclosure contains silicon oxide, an alkali metal, an oxide containing an alkaline earth metal, and water.

In addition, a method for manufacturing a light-emitting device according to the present disclosure includes providing a light-emitting element including a semiconductor structure, providing a mixture by mixing silicon oxide powder, an oxide containing an alkaline earth metal, and an alkaline solution containing an alkali metal, applying the mixture onto a region to be irradiated with light from the light-emitting element, and forming a light-reflective member by curing the mixture by heating.

According to the light-emitting device according to the present disclosure, a light-emitting device can be provided that includes a light-reflective member that can improve heat dissipation properties of the light-emitting device.

In addition, according to the inorganic member according to one aspect of the present disclosure, an inorganic member can be provided that can improve the performance of a light-reflective member.

Furthermore, according to the manufacturing method for the light-emitting device according to the present disclosure, it is possible to provide a manufacturing method for a light-emitting device that includes a light-reflective member having improved performance.

### BRIEF DESCRIPTION OF THE DRAWINGS

A more complete appreciation of embodiments of the disclosure and many of the attendant advantages thereof will be readily obtained by reference to the following detailed description when considered in connection with the accompanying drawings.

FIG. 1 is a schematic cross-sectional view of a light-emitting device according to a first embodiment of the present disclosure.

FIG. 2 is a partially enlarged cross-sectional view of a light-reflective member provided in the light-emitting device illustrated in FIG. 1.

FIG. 3A is a schematic cross-sectional view of a light-emitting device according to a second embodiment of the present disclosure.

FIG. 3B is a schematic top view of the light-emitting device illustrated in FIG. 3A.

FIG. 3C is a schematic top view illustrating another form of the light-emitting device illustrated in FIG. 3A.

FIG. 4A is a schematic cross-sectional view illustrating a step of a first manufacturing method for the light-emitting device illustrated in FIG. 1.

FIG. 4B is a schematic cross-sectional view illustrating a step of the first manufacturing method for the light-emitting device illustrated in FIG. 1.

FIG. 4C is a schematic cross-sectional view illustrating a step of the first manufacturing method for the light-emitting device illustrated in FIG. 1.

FIG. 5 is a schematic cross-sectional view illustrating another step of the first manufacturing method.

FIG. 6A is a schematic cross-sectional view illustrating a step of a second manufacturing method for the light-emitting device illustrated in FIG. 1.

FIG. 6B is a schematic cross-sectional view illustrating a step of the second manufacturing method for the light-emitting device illustrated in FIG. 1.

FIG. 6C is a schematic cross-sectional view illustrating a step of the second manufacturing method for the light-emitting device illustrated in FIG. 1.

FIG. 6D is a schematic cross-sectional view illustrating a step of the second manufacturing method for the light-emitting device illustrated in FIG. 1.

### DETAILED DESCRIPTION OF EMBODIMENT

### Description of Embodiments

Embodiments and examples for implementing the present invention are described below with reference to the drawings. Note that the light-emitting device and the manufacturing method for the light-emitting device described below are intended to embody technical concepts of the present invention, and the present invention is not limited to the following unless specifically stated.

In each drawing, members having identical functions may be denoted by the same reference characters. In view of the ease of explanation or understanding of the main points, the embodiments and examples may be illustrated separately for convenience, but the partial substitutions or combinations of the configurations illustrated in different embodiments and examples are possible. In the embodiments and examples to be described below, descriptions of matters common to those already described are omitted, and only different points are described. In particular, similar actions and effects of similar configurations shall not be mentioned sequentially for each embodiment and example. The sizes, positional relationship, and the like of members illustrated in the drawings may be exaggerated in order to clarify explanation.

A light-emitting device according to an embodiment of the present disclosure includes a light-emitting element, and a light-reflective member that includes an inorganic member and reflects light emitted from the light-emitting element. The inorganic member contains silicon oxide, an alkali metal, and a hydroxide containing an alkaline earth metal.

Here, the light-reflective member referred to in the present application includes
(1) a light-reflective member formed of an inorganic member, the inorganic member itself having light reflectivity, and
(2) a light-reflective member which contains a light-reflective material and in which an inorganic member mainly functions as a support.
   For example, in the case of (1) in which the light-reflective member is formed of the inorganic member, the inorganic member itself is white and has light reflectivity, for example.

In addition, in the case of (2) in which the light-reflective member contains the light-reflective material, for example, even when the inorganic member serving as the support has light transmissivity, the light-reflective member is caused to function as the light-reflective member having light-reflective properties imparted by the light-reflective material.

Furthermore, the inorganic member itself that functions as the support may have light reflectivity.

Embodiments according to the present disclosure will be described below in detail with reference to the drawings.

### First Embodiment

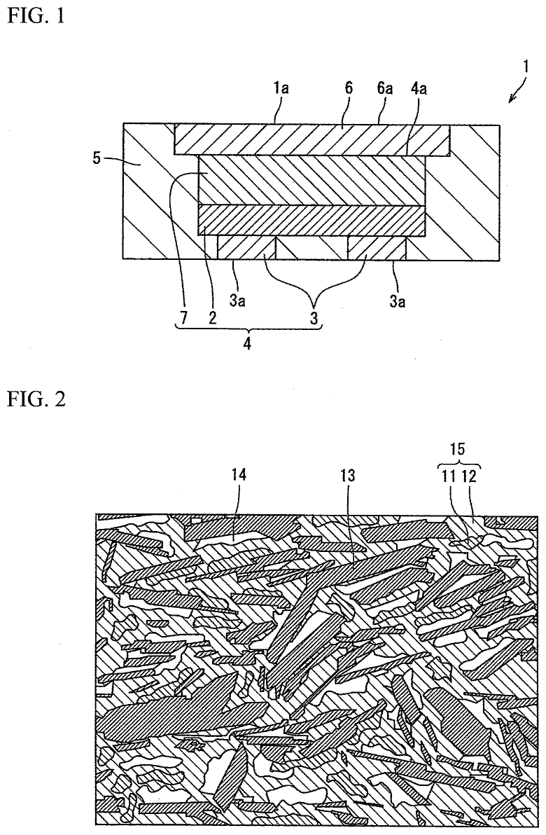

As illustrated in FIG. 1, a light-emitting device 1 according to the present embodiment includes a light-emitting element 4, and a light-reflective member 5 that covers the light-emitting element 4. Here, the light-emitting device 1 may include a light-transmissive member 6 that covers an upper surface 4a of the light-emitting elements 4. In the following first embodiment, the light-emitting device 1 including the light-transmissive member 6 will be described.

The light-emitting element 4 includes a semiconductor layered body 2, and a pair of electrodes 3 provided on the lower surface side of the semiconductor layered body 2. A part of a surface of the light-transmissive member 6 is exposed from the light-reflective member 5, and the surface, of the light-transmissive member 6, exposed from the light-reflective member 5 is included in a light emission surface 1a of the light-emitting device 1.

The light-reflective member 5 covers lateral surfaces and a part of the bottom surface (a portion of the bottom surface of the semiconductor layered body 2 which is not provided with the electrodes 3) of the light-emitting element 4, and lateral surfaces and a part of the bottom surface of the light-transmissive member 6.

Each component of the light-emitting device 1 according to the first embodiment will be described below in detail.

### Light-Emitting Element

A light-emitting element such as a light-emitting diode can be used as the light-emitting element 4. The semiconductor layered body 2 included in the light-emitting element 4 includes an n-type semiconductor layer, a p-type semiconductor layer, a light-emitting portion disposed between the n-type semiconductor layer and the p-type semiconductor layer, for example. The light-emitting element 4 includes a growth substrate 7 (e.g., a sapphire substrate) for growing a semiconductor layer on the surface of the semiconductor layered body 2 opposite to the surface of the semiconductor layered body 2 where the electrodes 3 are formed. It should be noted that the growth substrate may be removed after the semiconductor layer is formed. The n-type semiconductor layer, the p-type semiconductor layer, and a light-emitting layer can be formed, for example, using a nitride semiconductor (InₓAl_{y}Ga_{1-x-y}N (0≤x, 0≤y, x+y≤1)), and can emit visible light or ultraviolet light by appropriately setting the composition ratio. A light emission peak wavelength of the light-emitting element 4 is, for example, in a range of 260 nm to 630 nm. The light-emitting element 4 emits ultraviolet light or blue light, for example.

The pair of electrodes 3 provided on the lower surface side of the semiconductor layered body 2 are a p-electrode and an n-electrode.

### Light-Transmissive Member

The light-transmissive member 6 may contain a resin, or may be an inorganic material. In a case in which the light-transmissive member 6 is an inorganic material, a light-emitting device with high heat resistance can be produced because the light-transmissive member 6 which is an inorganic material has a higher heat resistance than a light-transmissive member containing a resin. As the inorganic material, glass, sapphire, or the like may be used, for example. The light-transmissive member 6 can contain a wavelength conversion material such as a phosphor. In a case in which the light-transmissive member 6 is a member whose base material is an inorganic material and contains a phosphor, yttrium aluminum garnet (YAG) can be used as the phosphor, and alumina or silica can be used as the base material, for example. Note that the wavelength conversion material need not be contained in the light-transmissive member 6. In this case, light from the light-emitting element 4 is emitted to the outside from the light emission surface 1a without being subjected to wavelength conversion.

### Light-Reflective Member

In the present embodiment, the light-reflective member 5 covers the light-emitting element 4 and the light-transmissive member 6, while exposing lower surfaces 3a of the electrodes 3 of the light-emitting element 4, and an upper surface 6a of the light-transmissive member 6. Here, the term “cover” includes not only a state in which the light-reflective member 5 is disposed in contact with the light-emitting element 4 and/or the light-transmissive member 6, but also a state in which the light-reflective member 5 is disposed with another member or a space (e.g., an air layer) interposed between light-reflective member 5 and the light-emitting element 4 and/or the light-transmissive member 6. In the present specification, the terms “cover”, “covering”, “covered” and the like also include the same states as “covers”.

The upper surface 6a of the light-transmissive member 6 exposed from the light-reflective member 5 is the light emission surface 1a of the light-emitting device 1. In a case in which the light-transmissive member 6 is not provided, the light-reflective member 5 exposes the upper surface 4a of the light-emitting element 4 and the lower surfaces 3a of the electrodes 3, for example. In this case, the upper surface 4a of the light-emitting element 4 is the light emission surface of the light-emitting device 1.

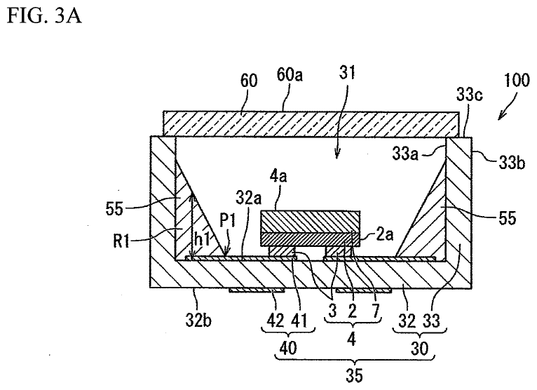

The light-reflective member 5 includes an inorganic member 15, and reflects light emitted from the light-emitting element 4. As schematically illustrated in FIG. 2, the inorganic member 15 includes a support member 12 containing silicon oxide and an alkali metal, and a hydroxide 11 containing an alkaline earth metal. By containing the hydroxide 11, the light-reflective member 5 can have improved performance. For example, by filling at least some of voids generated during the manufacturing process with the hydroxide 11, the void ratio is reduced, thereby improving the thermal conductivity of the light-reflective member 5. Specifically, in a case in which the light-reflective member is formed using a raw material containing silicon oxide, an alkali metal, and also an alkaline earth metal, the hydroxide 11 containing the alkaline earth metal is distributed in the inorganic member 15, and the open porosity can be reduced as compared with a case in which the light-reflective member containing silicon oxide and an alkali metal is formed without containing any alkaline earth metal. For example, the open porosity of the formed light-reflective member can be 40% or less and 20% or more. In addition, alkali metal ions generated during the manufacturing process can be efficiently removed in a rinsing step described below, and thus an occurrence of ion migration can be suppressed.

Here, the open porosity is an index indicating a degree of porosity, and is defined by Equation 1 below.

$$Open porosity ( \% ) = [ ( apparent density - bulk density ) / bulk density ] \times 100 \qquad Equation 1$$

The “apparent density” in Equation 1 is a density obtained by calculating a volume V1 of a member to be measured excluding protrusions, recesses, and voids connected to the outside, and dividing a weight W of the member to be measured by the volume V1. Therefore, the volume V1 includes voids that are not connected to the outside, and is not the true density of the member to be measured. The apparent density can be calculated based on, for example, the weight of the member to be measured in air (weight in air) and the weight of the member to be measured in water (weight in water) in consideration of the density of water. Here, the weight in water of the member is a weight measured by submerging the member in water and then drawing a vacuum. Protrusions, recesses, and voids connected to the outside are filled with water, but voids not connected to the outside are not filled with water.

In addition, the “bulk density” in Equation 1 is a density obtained by calculating a volume V2 of the member to be measured including protrusions, recesses, and voids connected to the outside, and dividing the weight W of the member to be measured by the volume V2. The bulk density can be calculated, for example, by measuring the volume V2 and the weight W of the formed light-reflective member, and performing calculation based on the measured volume V2 and weight W. The volume V2 of the formed light-reflective member can be measured with a laser microscope.

In addition, the alkali metal preferably includes potassium or sodium, and more preferably includes potassium. The alkali metal is a metal contained in an alkaline solution used in a step of forming the light-reflective member 5. The alkaline solution is a solution in which the alkali metal is dissolved in a solvent. For example, water can be used as the solvent. The alkaline solution in such a case is a potassium hydroxide solution or a sodium hydroxide solution, for example. When the alkali metal includes potassium or sodium, for example, the light-reflective member 5 being white, having light reflectivity and containing K₂SiO₃ or Na₂SiO₃ can be formed. For example, the light-reflective member 5 can be formed without containing a light-reflective material. In addition, when the light-reflective member 5 being white, having light reflectivity, and containing potassium contains a light-reflective material, the light-reflective member 5 having higher light reflectivity can be formed.

In addition, the alkaline earth metal preferably includes at least one selected from the group consisting of calcium, magnesium, and beryllium. When the alkaline earth metal includes at least one selected from the group consisting of calcium, magnesium, and beryllium, the hydroxide 11 containing the alkaline earth metal can be made white, and the light reflectivity of the light-reflective member 5 can be improved. The hydroxide 11 containing at least one selected from the group consisting of calcium, magnesium, and beryllium is, for example, a crystal of Ca(OH)₂, a crystal of Mg(OH)₂, or a crystal of Be(OH)₂. The alkaline earth metal more preferably includes calcium. When the alkaline earth metal includes calcium, the hydroxide 11 is obtained that is white and has high light reflectivity as compared with a case in which the alkaline earth metal includes another alkaline earth metal. As a result, the light reflectivity of the light-reflective member 5 can be further improved.

In addition, the content ratio of the hydroxide 11, which contains an alkaline earth metal, in the light-reflective member 5 is preferably in a range of 0.1 wt. % to 8.7 wt. %. When the content ratio of the hydroxide 11, which contains the alkaline earth metal, in the light-reflective member 5 is in the range from 0.1 wt. % to 8.7 wt. %, the thermal conductivity of the light-reflective member 5 can be further increased as compared with a case in which the content ratio of the hydroxide 11 containing the alkaline earth metal is out of the above range.

The light-reflective member 5 preferably further contains a light-reflective material 13, for example, including at least one selected from the group consisting of boron nitride, titanium oxide, zirconium oxide, and aluminum oxide. In that case, the light reflectance of the light-reflective member 5 can be further improved.

Here, in addition to having the function of reflecting light, boron nitride and aluminum oxide can function, for example, as an aggregate that suppresses expansion or contraction of the light-reflective member 5 due to heat generated by the light-emitting element 4 when the light-emitting device 1 is driven. In addition, titanium oxide and zirconium oxide can function as a light-scattering material. For the light-reflective material 13 functioning as the aggregate, it is preferable to use a material having a coefficient of linear expansion closer to that of the light-emitting element 4 than to that of the support member 12 in the light-reflective member 5.

The weight of the light-reflective material 13 in the light-reflective member 5 is, for example, between 1 and 4 times the weight of the silicon oxide in the light-reflective member 5. Within this range, shrinkage of a mixture during curing can be suppressed. When the weight ratio of the light-reflective material 13 becomes large, curability may deteriorate. On the other hand, when the weight ratio of silicon oxide is high, shrinkage due to curing may be increased, and cracks may occur during curing.

The mean particle diameter of silicon oxide is in a range of 0.1 μm to 10 μm, for example. By setting the mean particle diameter of silicon oxide within this range, the density per volume of the raw materials (such as the light-reflective materials 13 and silicon oxide) can be improved. Thus, the strength of the light-reflective member 5 can be increased.

When the light-reflective member 5 contains the light-reflective materials 13 functioning as the aggregate, the mean particle diameter of silicon oxide is desirably smaller than the mean particle diameter of the light-reflective materials 13 functioning as the aggregate. In this way, at the time of mixture, silicon oxide can fill the voids formed between the light-reflective materials 13 functioning as the aggregate. The mean particle diameter of silicon oxide is calculated by measuring the granularity distribution of silicon oxide by a laser diffraction method.

The light-reflective material 13 functioning as the aggregate is preferably a particle having a plate-like or scale-like shape. The average aspect ratio of the light-reflective materials 13 functioning as the aggregate and having the plate-like or scale-like shape is preferably 10 or more, more preferably in a range of 10 to 70. In this way, the light-reflective material 13 can more effectively function as the aggregate. As described above, the light-reflective material 13 functioning as the aggregate and being the plate-like or scale-like particle can suppress expansion or contraction of the light-reflective member 5 due to heat generated by the light-emitting element 4. Thus, heat resistance of the light-emitting device 1 can be improved.

Here, the average aspect ratio of the light-reflective materials 13 functioning as the aggregate can be calculated by the following method.

### Calculation Method of Average Aspect Ratio

The average aspect ratio of the light-reflective materials 13 is calculated by measuring the thicknesses and the widths of the light-reflective materials 13 contained in the light-reflective member 5, in a cross-section of the light-emitting device 1.

First, a cross-section that passes through the center of the light emission surface 1a of the light-emitting device 1 and is substantially orthogonal to the light emission surface 1a is exposed. This cross-section is exposed by cutting the light-emitting device 1.

Subsequently, the exposed cross-section is mirror-polished, the mirror-polished cross-section is imaged with a scanning electron microscope (SEM), the cross-sections of the light-reflective materials 13 are extracted, and a measurement region including the cross-sections of approximately 1000 light-reflective materials 13 is selected. The number of pixels of the microscope is set to approximately 20 megapixels, and the magnification is set to 500× to 3000×.

Subsequently, with image analysis software, the width (the length in the long side direction of the cross-section of the light-reflective material) and the thickness (the length in the short side direction of the cross-section of the light-reflective material) of each of the extracted cross-sections of the light-reflective materials 13 are measured at one point each to calculate the percentage of the widths relative to the thicknesses. Then, the average value of the measurement values of the measured light-reflective materials 13 is set as the average aspect ratio. The average aspect ratio of the light-reflective materials 13 functioning as the aggregate can be set appropriately based on the material of the light-reflective material 13, and when the light-reflective materials 13 are boron nitride, the average aspect ratio of the light-reflective materials 13 is in a range of 16.5 to 19.2, for example. When the light-reflective materials 13 are aluminum oxide, the average aspect ratio of the light-reflective materials 13 is in a range of 10 to 70, for example.

In addition, the mean particle diameter of the light-reflective materials 13 is set within a preferable range described later, in consideration of the characteristics of the material of the light-reflective materials 13.

Here, the mean particle diameter of the light-reflective materials 13 functioning as the aggregate is calculated as follows.

### Calculation Method of Mean Particle Diameter

The particle diameters of the light-reflective materials 13 functioning as the aggregate are calculated by using a scanning electron microscope “TM3030Plus” available from Hitachi High-Tech Corporation.

First, one surface of a double-sided tape formed of carbon is attached to a sample stage of the microscope, and thereafter the light-reflective materials 13 are disposed on the other surface of the double-sided tape. The number of pixels of the microscope is set to 1.23 megapixels, and the magnification is set to 1000× to 2000× to acquire the image of a predetermined number (e.g., 100) of the light-reflective materials 13. Thereafter, the particle diameter of each particle is measured with image analysis software. In the present specification, the particle diameter of each of the light-reflective materials 13 is a maximum diameter of the light-reflective material 13. Subsequently, a median diameter of the measured particle is calculated, and the calculated value is set as the mean particle diameter of the light-reflective materials 13. In addition, the particle diameters of the light-reflective materials 13 may be calculated by extracting the cross-section of the covering member with the SEM and measuring them with the image analysis software.

When the light-reflective materials 13 are boron nitride, the mean particle diameter of the light-reflective materials 13 is in a range of 0.6 μm to 43 μm, for example. When the light-reflective materials 13 are alumina, the mean particle diameter of the light-reflective materials 13 is in a range of 0.6 μm to 10 μm, for example.

With the light-reflective materials 13 having the mean particle diameter and the average aspect ratio as described above, the light-reflective member 5 can effectively suppress expansion and contraction of the light-reflective member 5 due to heat generated by the light-emitting element 4, and the light-emitting device 1 having high heat resistance can be configured. In addition, the light-reflective member 5 preferably contains boron nitride as the light-reflective materials 13. When the light-reflective materials 13 are boron nitride, the light-reflective materials 13 can more effectively function as the aggregate.

The coefficient of thermal expansion of the light-reflective member 5 can be set in a preferable range by the content ratio of the light-reflective materials 13 functioning as the aggregate, and the average aspect ratio and the mean particle diameter of the light-reflective materials 13 functioning as the aggregate. The coefficient of thermal expansion of the light-reflective member 5 can be measured by a thermomechanical analyzer (TMA), for example. The coefficient of thermal expansion of the light-reflective member 5 is preferably in a range of 0.05 ppm to 5 ppm in a temperature range from 40° C. to 300° C. In this case, even when the temperature of the light-reflective member 5 is increased during the use of the light-emitting device 1, expansion and contraction of the light-reflective member 5 can be suppressed, and thus the reliability can be improved. The coefficient of thermal expansion of the light-reflective member 5 is, for example, approximately 1 ppm at 180° C.

In addition, the light-reflective member 5 may contain the light-reflective materials 13 functioning as the scattering material instead of or in addition to the light-reflective materials 13 functioning as the aggregate. As described above, the light-reflective materials 13 functioning as the scattering material are, for example, zirconium oxide or titanium oxide. When the light-emitting element 4 emits ultraviolet light, it is preferable to use zirconium oxide, which absorbs less light in the ultraviolet wavelength region.

Furthermore, by the light-reflective member 5 containing the light-reflective materials 13 functioning as the scattering material in addition to the light-reflective materials 13 functioning as the aggregate, the light reflectance of the light-reflective member 5 can be improved. Thus, the luminance difference between a light-emitting surface of the light-emitting device 1 and the upper surface (non-light-emitting surface) of the light-reflective member 5 surrounding the light-emitting surface in a top view can be made steep, and visibility on the light-emitting surface side of the light-emitting device 1 can be improved.

Titanium oxide used as the light-reflective material 13 may be titanium oxide alone, or titanium oxide subjected to surface treatment, such as formation of a coating film including silicon oxide, aluminum oxide, zirconium oxide, zinc, an organic material, or the like on the surface thereof, may be used. Zirconium oxide used as the light-reflective material 13 may be zirconium oxide alone, or zirconium oxide subjected to surface treatment, such as formation of a coating film including silicon oxide, aluminum oxide, zinc, an organic material, or the like on the surface thereof, may be used.

The mean particle diameter of the light-reflective materials 13 functioning as the scattering material contained in the light-reflective member 5 is desirably smaller than the mean particle diameter of the light-reflective materials 13 functioning as the aggregate. In this case, for example, the light-reflective materials 13 functioning as the scattering material can be disposed in gaps between the light-reflective materials 13 functioning as the aggregate, light emitted from the light-emitting element 4 can be inhibited from being emitted to the outside of the light-emitting device 1 through the gaps between the light-reflective materials 13 functioning as the aggregate, and thus the visibility on the light-emitting surface 1a of the light-emitting device 1 can be improved. Here, the mean particle diameter of the light-reflective materials 13 functioning as the scattering material is measured by a laser diffraction method.

Since the light-reflective member 5 configured as described above includes the support member 12 containing silicon oxide and an alkali metal, and the hydroxide 11 containing an alkaline earth metal, voids can be filled with the hydroxide 11 to reduce the void ratio. Thus, the thermal conductivity of the light-reflective member 5 can be increased to improve the heat dissipation properties thereof.

In addition, since the light-reflective member 5 contains the light-reflective materials 13 functioning as the aggregate, expansion and contraction of the light-reflective member 5 due to heat generated by the light-emitting element 4 can be suppressed, and thus the heat resistance of the light-emitting device 1 can be increased.

The light-emitting device 1 according to the first embodiment configured as described above can suppress a temperature rise of the light-emitting device 1 by efficiently dissipating heat generated by the light-emitting element 4 and the like, and can thus have high reliability.

In addition, in the light-emitting device 1 according to the first embodiment, by the light-reflective member 5 containing the light-reflective materials 13 functioning as the aggregate, a difference in the coefficient of thermal expansion between the light-reflective member 5 and the light-emitting element 4 can be reduced, a deterioration in the performance of the light-emitting device 1 can be reduced even after repeated use for a long period of time, and thus a highly reliable light-emitting device can be provided.

### Second Embodiment

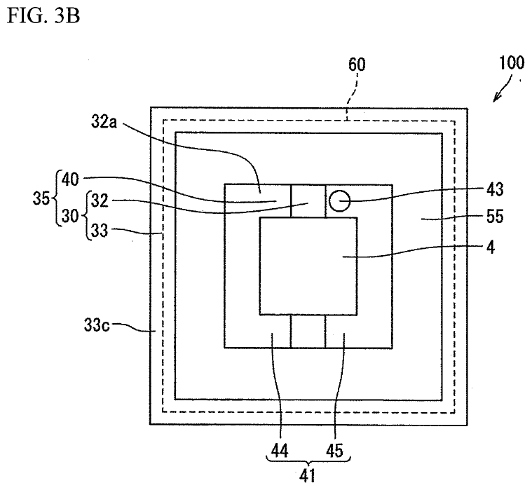

A light-emitting device 100 according to a second embodiment includes a base 35, the light-emitting element 4, and a light-reflective member 55, as illustrated in FIGS. 3A to 3C. The light-emitting element 4 and the light-reflective member 55 are disposed over the base 35. The light-emitting element 4 includes the semiconductor layered body 2. The lateral surfaces of the semiconductor layered body 2 are spaced apart from the light-reflective member 55. The light-emitting device 100 may further include a light-transmissive member 60 and a protective element 80. In FIGS. 3B and 3C, in order to facilitate understanding of configurations of the base 35, the light-emitting elements 4, and the light-reflective member 55, the light-transmissive member 60 is indicated by broken lines, and configurations obtained when seeing through the light-transmissive member 60 are indicated by solid lines.

Each member of the light-emitting device 100 according to the second embodiment will be described below.

### Base

The base 35 includes a bottom portion 32 and a wall portion 33 that define a recessed portion 31. The recessed portion 31 is a space surrounded by the bottom portion 32 and the wall portion 33. The bottom portion 32 and the wall portion 33 may be formed of the same material or may be formed of different members.

A base material 30 of the base 35 can be formed of a single material of an insulating material such as glass, a ceramic, resin, wood, or pulp, or a conductive material such as a semiconductor or a metal (e.g., copper, silver, gold, or aluminum), or can be formed of a composite material thereof. In particular, the base material 30 is preferably a metal, a ceramic, or the like, and more preferably a ceramic, which is an inorganic material. Examples of the ceramic include alumina, aluminum nitride, silicon nitride, and mullite, and particularly, aluminum nitride having high heat dissipation properties is preferable.

The base 35 includes a conductive member 40. As illustrated in FIG. 3A, the conductive member 40 includes a wiring layer 41 and external electrodes 42. The wiring layer 41 is disposed on an upper surface 32a of the bottom portion 32 and is electrically connected to the electrodes 3 of the light-emitting element 4 described later. The external electrodes 42 are disposed on a lower surface 32b of the bottom portion 32 and are electrically connected to an external terminal. The wiring layer 41 and the external electrodes 42 are electrically connected to each other through a via (through hole) formed in the bottom portion 32. In addition, as illustrated in FIGS. 3B and 3C, the wiring layer 41 includes an anode-side wiring layer 44 and a cathode-side wiring layer 45.

The base 35 includes an identification mark 43 disposed on the upper surface 32a of the bottom portion 32. As illustrated in FIGS. 3B and 3C, the identification mark 43 is exposed from the light-reflective member 55 in a top view. In the light-emitting device 100, the anode-side wiring layer 44 and the cathode-side wiring layer 45 can be identified by the identification mark 43.

In the example illustrated in FIG. 3A, the thickness of the wall portion 33 of the base 35 is uniform in a cross-sectional view. An inner lateral surface 33a of the wall portion 33 of the body 35 may have a step. As illustrated in FIGS. 3B and 3C, the outer peripheral shape of the wall portion 33 of the base 35 is a rectangular shape in a top view. Here, the rectangular shape is a shape including four sides and four corner portions, and the corner portions may each have a right-angled shape, a rounded shape, a shape chamfered in an arc shape, or the like. In addition, the inner peripheral shape of the wall portion 33 of the base 35 is a rectangular shape. The shape of the wall portion 33 is not limited to any of the shapes described above, and may be any known shape.

### Light-Transmissive Member

In the light-emitting device 100 according to the second embodiment, the configuration of the light-transmissive member 60 will be described with respect to points different from the light-transmissive member 60 of the light-emitting device 1 according to the first embodiment, and description of the same configuration will be omitted.

In the example illustrated in FIG. 3A, the light-transmissive member 60 is disposed on an upper surface 33c of the wall portion 33 of the base 35. The light-transmissive member 60 is, for example, a plate-like member having two primary surfaces. One primary surface 60a of the light-transmissive member 60 is the upper surface of the light-emitting device 100.

### Light-Emitting Element

The light-emitting element 4 is disposed over the bottom portion 32 of the base 35 in the recessed portion 31. One light-emitting element 4 may be disposed over the bottom portion 32 of the base 35, or two or more light-emitting elements 4 may be disposed over the bottom portion 32 of the base 35. In the light-emitting device 100 according to the second embodiment, the configuration other than the arrangement of the light-emitting element 4 is the same as that of the first embodiment, and description of a specific configuration is omitted.

The pair of electrodes 3 provided on the lower surface of the semiconductor layered body 2 is electrically connected to the wiring layer 41, as illustrated in FIG. 3A. The pair of electrodes 3 provided on the lower surface of the semiconductor layered body 2 are a p-electrode and an n-electrode.

Note that the light-emitting element 4 illustrated in FIGS. 3B and 3C has a rectangular shape in a top view. However, the shape of the light-emitting element 4 in a top view may be any known shape.

### Protective Element

The protective element 80 can be disposed on the bottom portion 32 of the base 35. The protective element 80 is, for example, a Zener diode. A lower electrode is provided on the lower surface of the protective element 80. The lower electrode of the protective element 80 is bonded to the cathode-side wiring layer 45, for example, via solder or conductive paste, and is electrically connected to the cathode-side wiring layer 45. An upper electrode is disposed on the upper surface of the protective element 80. The upper electrode of the protective element 80 is electrically connected to the wiring layer 44 on the anode side via a conductive wire 81. In the example illustrated in FIG. 3C, the protective element 80 is covered with the light-reflective member 55. By the light-reflective member 55 covering the protective element 80, it is possible to inhibit a decrease in the light extraction efficiency of the light-emitting device 100 due to the light emitted from the light-emitting element 4 being absorbed by the protective element 80.

### Light-Reflective Member

In the light-emitting device 100 according to the second embodiment, the configuration of the light-reflective member 55 will be described with respect to points different from the light-reflective member 5 of the light-emitting device 1 according to the first embodiment, and description of the same configuration as that of the light-reflective member 5 will be omitted.

The light-reflective member 55 reflects light emitted from the light-emitting element 4 in a light extraction direction. A direction in which the light reflected by the light-reflective member 5 is extracted from the light-emitting device 100 is an upward direction from the base 35.

As illustrated in FIG. 3A, the light-reflective member 55 is disposed on the bottom portion 32 of the base 35 along the inner lateral surface 33a of the wall portion 33 of the base 35.

As illustrated in FIG. 3B, the light-reflective member 55 continuously surrounds the entire periphery of the light-emitting element 4. In the light-emitting device 100, the outer peripheral shape of the light-emitting element 4, and the recessed portion 31 are rectangular in a top view, and the light-emitting element 4 is disposed in the recessed portion 31 such that the lateral surfaces of the light-emitting element 4 are parallel to the inner lateral surface 33a of the wall portion 33 facing the lateral surfaces of the light-emitting element 4.

In addition, as illustrated in FIG. 3A, the light-reflective member 55 is disposed over the inner lateral surface 33a of the wall portion 33 and the upper surface 32a of the bottom portion 32, so as to have an inclined surface whose height h1 from the upper surface 32a of the bottom portion 32 decreases from the wall portion 33 toward the light-emitting element 4. An end portion P1 of the light-reflective member 55 on the upper surface 32a side of the bottom portion 32 may be located at any position between the wall portion 33 and the light-emitting element 4, or may be in contact with one of the electrodes 3 of the light-emitting element 4. However, it is desirable that the end portion P1 is spaced apart from a lateral surface 2a of the semiconductor layered body 2. In this way, light emitted from the lateral surface 2a of the semiconductor layered body 2 can be emitted upward by the light-reflective member 55. Here, the inclination angle of the inclined surface of the light-reflective member 55 (the angle with respect to the upper surface 32a of the bottom portion 32 of the recessed portion 31) is set such that light of the light-emitting device 100 is emitted at a desired light distribution angle.

In the example illustrated in FIG. 3A, in the light-emitting device 100, the inclined surface of the light-reflective member 55 has a linear shape in a cross-sectional view. However, the inclined surface may be appropriately set such that the light of the light-emitting device is emitted with desired light distribution characteristics. For example, the shape of the inclined surface of the light-reflective member 55 in a cross-sectional view may be a curved shape recessed toward the base 35, or a curved shape bulging toward the lateral surface of the light-emitting element 4.

In the light-emitting device 100, in the example illustrated in FIG. 3A, the light-reflective member 55 is disposed such that the upper end of the light-reflective member 55 is positioned lower than the upper end of the inner lateral surface 33a of the wall portion 33, but the light-reflective member 55 may be disposed such that the upper end of the light-reflective member 55 and the upper end of the inner lateral surface 33a coincide with each other. In addition, the light-reflective member 55 may be continuously disposed on the upper surface 33c of the wall portion 33.

The light-emitting device 100 according to the second embodiment configured as described above can increase the heat dissipation properties of the light-reflective member 55 disposed on the bottom portion 32 of the base 35 along the inner lateral surface 33a of the wall portion 33 of the base 35. In this way, heat generated by the light-emitting element 4 can be efficiently dissipated, the temperature rise of the light-emitting device 1 can be suppressed, and a highly reliable light-emitting device can thus be provided.

That is, it is preferable that the base 35 has high heat dissipation properties. However, even when the heat dissipation properties of the base 35 are enhanced, if the heat dissipation properties (thermal conductivity) of the light-reflective member 55 are low, the heat dissipation properties through the base 35 deteriorate.

However, by increasing the heat dissipation properties of the light-reflective member 55, heat can be efficiently dissipated through the base 35.

In addition, for example, when the light-emitting device 100 according to the second embodiment configured as described above is applied as a light-emitting device that emits ultraviolet light, manufacturing costs can be reduced.

For example, compared with light emitted by a light-emitting element that emits visible light, light emitted by a light-emitting element that emits ultraviolet light has a great amount of energy, which is more likely to cause degradation of resin by light, and thus a base formed of a ceramic that is highly durable against light energy is normally used. However, in the light-emitting device 100 according to the second embodiment configured as described above, since a portion of a surface of the base 35, which is mainly irradiated with light emitted from the light-emitting element 4, can be covered with the light-reflective member 55, the base 35 formed of resin can be employed. In general, the base formed of resin is less expensive than the base formed of a ceramic. Thus, the light-emitting device 100 according to the second embodiment can be made less expensive by employing the base 35 formed of resin.

In the light-emitting device 100 according to the second embodiment, the light-reflective member 55 continuously surrounds the entire periphery of the light-emitting element 4. However, the light-reflective members 55 may be disposed so as to be spaced apart from each other around the light-emitting element 4. For example, as illustrated in FIG. 3C, the light-reflective members 55 may be disposed at four corner portions of the inner lateral surface 33a of the wall portion 33 so as to be spaced apart from each other. Alternatively, the light-reflective member 55 may be divided into two portions, one of which is disposed continuously over two adjacent corner portions, of the four corner portions of the inner lateral surface 33a of the wall portion 33, and the other of which is disposed continuously over the remaining two corner portions.

In the example of a light-emitting device 100A illustrated in FIG. 3C, the light-reflective member 55 has a substantially triangular pyramid shape having a corner of the rectangular shape of the recessed portion 31 as the vertex, with the height thereof decreasing toward the bottom portion and the bottom surface thereof shaped in a substantially isosceles triangle.

In addition, as illustrated in FIG. 3C, in the light-emitting device 100A, in a top view, each of the four sides of the rectangular shape, which is the outer peripheral shape of the light-emitting element 4, is not parallel to any side of the rectangular shape, which is the outer peripheral shape of the base 35. Specifically, the light-emitting element 4 is disposed such that the four lateral surfaces of the light-emitting element 4 face the light-reflective members 55 disposed at the four corner portions, respectively. That is, in a top view, the angle formed by the lateral surface of the light-emitting element 4 and the wall portion 33 is set to approximately 45 degrees. In this way, light emitted from the lateral surface of the light-emitting element 4 is effectively reflected by the light-reflective member 55.

Note that, in the light-emitting device 100 according to the second embodiment, in a top view, each of the four sides of the rectangular shape, which is the outer peripheral shape of the light-emitting element 4, may be non-parallel to any side of the rectangular shape, which is the outer peripheral shape of the base 35.

### Third Embodiment

A manufacturing method according to a third embodiment of the present disclosure will be described below.

A manufacturing method according to an embodiment of the present disclosure includes
a step of providing a light-emitting element including a semiconductor structure,
a step of providing a mixture by mixing silicon oxide powder, an oxide containing an alkaline earth metal, and an alkaline solution containing an alkali metal,
a step of applying the mixture onto a region to be irradiated with light from the light-emitting element, and
a step of forming a light-reflective member by curing the mixture by heating.
   Each of the steps will be specifically described below.

### Step of Providing Light-Emitting Element

In this step, the light-emitting element 4 is provided that includes a growth substrate 7 (e.g., a sapphire substrate) and the semiconductor layered body 2 provided on the growth substrate 7. Here, the semiconductor layered body 2 includes an n-type semiconductor layer, a p-type semiconductor layer, and a light-emitting portion disposed between the n-type semiconductor layer and the p-type semiconductor layer. In addition, the light-emitting element 4 includes the electrodes 3 on an electrode forming surface, of the semiconductor layered body 2, positioned on the opposite side to the growth substrate 7.

### Step of Providing Mixture

In this step, mixed powder, which is obtained by mixing silicon oxide powder and an oxide containing an alkaline earth metal, is mixed with an alkaline solution containing an alkali metal, to provide a mixture. The mixed powder and the alkaline solution are mixed such that they are mixed until a uniform viscosity is obtained, and then degassed and agitated with an agitation degassing machine that can perform agitation under reduced pressure, for example.

The mean particle diameter of the silicon oxide powder is in a range of 0.1 μm to 10 μm, for example. The mean particle diameter of the oxide containing the alkaline earth metal is in a range of 10 μm to 35 μm, for example. The concentration of the alkaline solution is in a range of 1 mol/L and 8 mol/L, for example. When the concentration of the alkaline solution is in this range, curability at the time of heating described later can be improved. In addition, the content ratio of the oxide containing the alkaline earth metal in the mixture is preferably in a range of 0.1 wt. % to 6.6 wt. %, and by setting the content ratio of the oxide containing the alkaline earth metal in this range, a light-reflective member can be formed which has a low open porosity and in which generation of cracks is suppressed during heating.

In addition, the mixture may contain light-reflective material powder, and when the mixture contains the light-reflective material powder, the content of the light-reflective material powder is, for example, in a range of one time to four times the content of the silicon oxide powder in weight ratio. The light-reflective material powder is, for example, powder of boron nitride, titanium oxide, zirconium oxide, or aluminum oxide. When the light-reflective material powder to be contained in the mixture is boron nitride, the mean particle diameter of the light-reflective material powder is in a range of 0.6 μm to 43 μm, for example. When the light-reflective material powder to be contained in the mixture is aluminum oxide, the mean particle diameter of the light-reflective material powder is in a range of 0.6 μm to 10 μm, for example.

When the light-reflective material powder to be contained in the mixture is boron nitride or aluminum oxide, the average aspect ratio of the light-reflective material powder is 10 or greater and preferably in a range of 10 to 70. When the light-reflective material powder to be contained in the mixture is titanium oxide or zirconium oxide, the mean particle diameter of the light-reflective material powder is in a range of 0.01 μm to 70 μm, for example. When the light-reflective material powder of boron nitride or aluminum oxide is contained in addition to the light-reflective material powder of boron nitride or aluminum oxide, the mean particle diameter of the light-reflective material powder of boron nitride or aluminum oxide is smaller than, for example, the mean particle diameter of the light-reflective material powder of boron nitride or aluminum oxide.

The alkaline solution and the mixed powder are mixed at a weight ratio in a range of 1.0:1.3 to 1.0:2.6, for example. By setting the weight ratio of the alkaline solution with respect to the mixed powder in the above range, the mixed powder can be easily mixed uniformly, and a light-reflective member having a high strength can be easily formed.

### Step of Applying Mixture

This step is a step of applying the mixture to a region corresponding to a region where the light-reflective member 5 illustrated in FIG. 1 or the light-reflective member 55 illustrated in FIGS. 3A to 3C is provided, and this step will be specifically described in a manufacturing method for the light-emitting device according to the first embodiment and a manufacturing method for the light-emitting device according to the second embodiment, which will be described later.

### Step of Forming Light-Reflective Member

In this step, the mixture applied onto a region to be irradiated with light from the light-emitting element is cured by heating, to form a light-reflective member having light reflectivity. By the heating, the alkali metal and the silicon oxide contained in the mixture react with each other, resulting in forming the light-reflective member containing alkali metal ions. This step includes, for example, a temporary curing step of curing the mixture at a first temperature T1 and a main curing step of curing the mixture at a second temperature T2 higher than the first temperature T1. The temporary curing step is performed at the first temperature T1 in a range of 80° C. to 100° C. for a range from 10 minutes to two hours, for example. The main curing step is performed at the second temperature T2 in a range of 150° C. to 250° C. for a range from 10 minutes to three hours, for example. In this manner, by performing the temporary curing step at a lower temperature than that of the main curing step before the main curing step is performed, cracks are less likely to occur in the formed light-reflective member 5, 55.

Furthermore, by performing the temporary curing step and the main curing step while applying pressure, voids in the formed light-reflective member can be reduced, and thus the light reflectance and the thermal conductivity of the formed light-reflective member 5, 55 can be increased. The pressure applied during the main curing step is, for example, 1 MPa.

According to the manufacturing method according to the embodiment of the present disclosure described above, since the light-reflective member having excellent heat dissipation properties can be formed in the region to be irradiated with the light from the light-emitting element, the temperature rise of the light-emitting device can be suppressed, and a highly reliable light-emitting device can thus be manufactured.

### Step of Rinsing

The manufacturing method of the light-emitting device 1 according to the present embodiment can include a step of rinsing the light-reflective member 5, 55 after the step of forming the light-reflective member 5, 55. In the step of forming the light-reflective member, alkali metal ions are generated as described above. Thus, by performing rinsing with water, alkali metal ions attached to the surface of the light-emitting device 1 can be removed. As a result, the light-emitting device 1 having high reliability can be manufactured.

The manufacturing method of the light-emitting device 1 according to the present embodiment can include a step of drying the light-reflective member 5, 55 after the rinsing step.

A manufacturing method for the light-emitting device 1 according to the first embodiment and a manufacturing method for the light-emitting device 100 according to the second embodiment will be described below.

In the following description, the step of providing the light-emitting element, the step of providing the mixture, and the step of forming the light-reflective member by curing the mixture by heating are the same as those described above, and thus description of these steps will be omitted or simplified.

### First Manufacturing Method

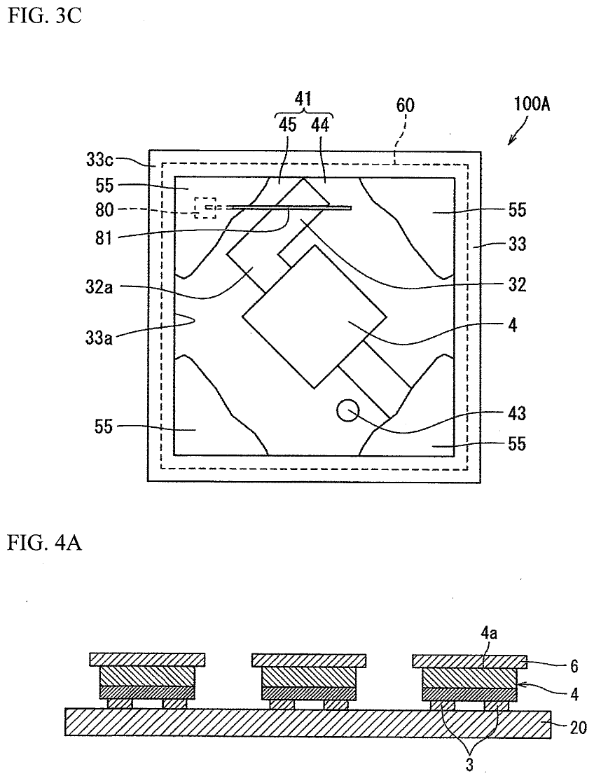

With reference to FIGS. 4A to 4C, an exemplary manufacturing method (first manufacturing method) for the light-emitting device 1 according to the first embodiment will be described.

### Step of Mounting Light-Emitting Element on Mounting Substrate

First, a plurality of the light-emitting elements 4 each having the upper surface 4a provided with the light-transmissive member 6 are provided. The light-transmissive member 6 contains phosphor. Subsequently, as illustrated in FIG. 4A, the light-emitting elements 4 are mounted on a mounting substrate 20 at a predetermined interval.

Step of Applying Mixture onto Light-Emitting Element

In this step, a mixture 50 provided in the above-described step of providing the mixture is applied onto the mounting substrate 20 so as to cover the plurality of light-emitting elements 4, as illustrated in FIG. 4B. Upon or after applying the mixture 50 onto the mounting substrate 20, for example, the mounting substrate 20 is preferably vibrated in the vertical direction and/or the horizontal direction. In this way, the mixture 50 can be uniformly applied.

In addition, before applying the mixture 50, a protective film may be formed on the electrodes 3 and/or wiring electrodes of the mounting substrate 20. In this way, it is possible to suppress damage such as corrosion of the electrodes 3 and/or the wiring electrodes of the mounting substrate 20 due to the alkaline solution contained in the mixture 50. In addition, by forming the protective film on the electrodes 3 and/or the wiring electrodes of the mounting substrate 20, it is possible to suppress damage due to corrosion gas in the atmosphere and the like during the use of the manufactured light-emitting device 1. That is, the gas barrier properties of the light-emitting device 1 can be improved. The above-described protective film can be formed by atomic layer deposition (ALD).

In addition, after disposing the mixture 50 on the mounting substrate 20, for example, by pressing the mixture 50 with a glass plate, the upper surface of the mixture 50 can be formed in a flat shape.

In addition, before applying the mixture 50, a film of silicon oxide or aluminum oxide may be formed on the mounting substrate 20, and in this way, the adhesion strength between the mounting substrate 20 and the mixture 50 can be improved.

Subsequently, in the step of forming the light-reflective member described above, the mixture 50 is cured to form the light-reflective member 5.

### Step of Exposing Light-Transmissive Member

Subsequently, as illustrated in FIG. 4C, the light-reflective member 5 covering the upper surface 6a of the light-transmissive member 6 is ground to be removed, to expose the upper surface 6a of the light-transmissive member 6. The upper surface 6a of the light-transmissive member 6 exposed at this time serves as the light emission surface 1a of the light-emitting device 1. In this way, an intermediate is formed that includes the mounting substrate 20, the plurality of light-emitting elements 4, a plurality of the light-transmissive members 6 respectively disposed on the upper surfaces 4a of the light-emitting elements 4, and the light-reflective member 5.

### Step of Dicing

Subsequently, the light-emitting device 1 is obtained through dicing the intermediate by cutting the light-reflective member 5 along a predetermined cutting position CL, so as to include one of the light-emitting elements 4. The dicing is performed by using a blade, for example.

In the first manufacturing method, the mixture 50 is applied covering the upper surface 6a of the light-transmissive member 6 in the step of applying the mixture, and the upper surface 6a of the light-transmissive member 6 is exposed in the succeeding step of exposing the light-transmissive member. However, the upper surface 6a of the light-transmissive member 6 may be exposed and the mixture 50 may be disposed on the mounting substrate 20 in the step of applying the mixture. In this way, the step of exposing the light-transmissive member may be omitted.

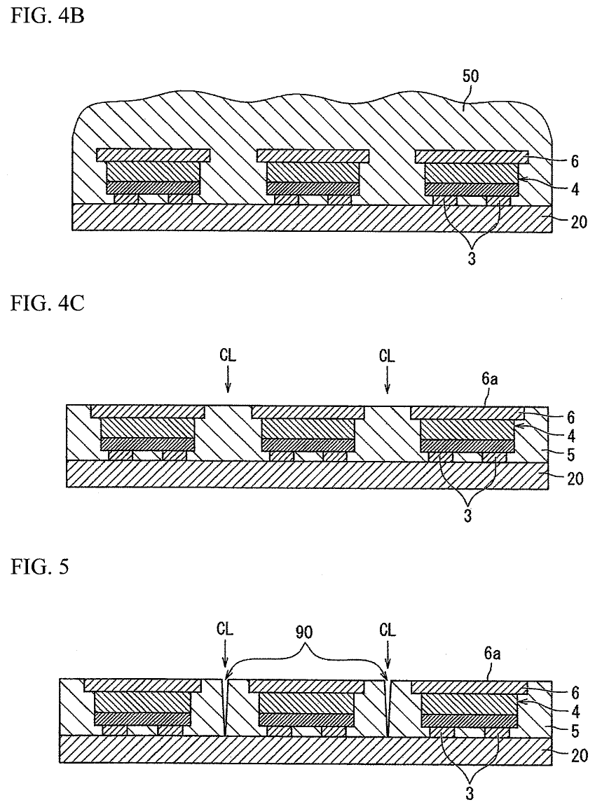

In this manner, as illustrated in FIG. 5, grooves 90 are desirably formed in the mixture 50 after the step of applying the mixture and before a step of heating. The grooves 90 are each desirably disposed along the cutting position CL in the step of dicing. In addition, it is desirable to divide the covering member through the formation of the grooves 90. In this way, the shrinkage stress generated during curing is directed from the positions where the grooves 90 are formed to the light-emitting element 4 side, and thus peeling of the light-emitting elements 4 from the mixture 50 during curing can be inhibited. As a result, the bonding strength between the light-reflective member 5 formed by curing the mixture 50, and each of the light-emitting elements 4 can be increased. The formation of the grooves 90 is performed by using a blade, for example. In a case in which the grooves 90 are formed before the step of heating, it is preferable to expose the upper surface 6a of the light-transmissive member 6 and apply the mixture 50 in the step of applying the mixture 50 preceding the step of forming the grooves 90, in which case the shapes of the grooves 90 formed in the mixture 50 can be easily maintained.

In the above-described step of dicing, the dicing is performed such that one light-emitting element is included in one light-emitting device. It should be noted that this is not limitative, and the dicing may be performed such that two or more light-emitting elements are included in one light-emitting device. The same applies to the second manufacturing method described below.

### Second Manufacturing Method

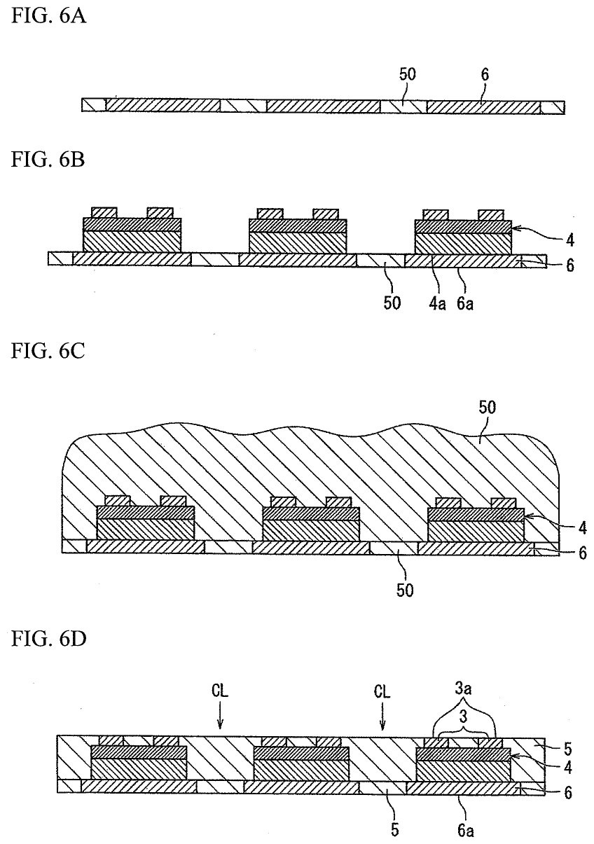

Next, with reference to FIGS. 6A to 6D, another exemplary manufacturing method (second manufacturing method) for the light-emitting device 1 according to the first embodiment will be described.

### Step of Providing Light-Transmissive Member Assembly

Here, as illustrated in FIG. 6A, a light-transmissive member assembly is provided in which a plurality of the light-transmissive members 6 are supported by the mixture 50 in a state where the upper surfaces and the lower surfaces of the light-transmissive members 6 are exposed. The light-transmissive member assembly is provided, for example, in the following manner.

First, the plurality of light-transmissive members 6 are provided, and the mixture 50 is provided as in the first manufacturing method.

Subsequently, the provided mixture 50 is formed, for example, in a layer shape on a support substrate, a plurality of through holes for disposing the light-transmissive members 6 are provided in the mixture 50 having the layer shape, and the light-transmissive members 6 are disposed in the respective through holes.

Then, the support substrate is removed to provide the light-transmissive member assembly in which the plurality of light-transmissive members 6 are supported by the mixture 50 in the state where the upper surfaces and the lower surfaces of the light-transmissive members 6 are exposed, as illustrated in FIG. 6A. The obtained light-transmissive member assembly can support the light-transmissive members 6 due to the thixotropy of the mixture 50 containing the above-described materials.

### Step of Placing Light-Emitting Element on Light-Transmissive Member

Subsequently, as illustrated in FIG. 6B, a plurality of the light-emitting elements 4 are placed on the plurality of light-transmissive members 6, respectively. Note that here, the surface, of each of the light-emitting elements 4, opposite to the surface on which the electrodes 3 are formed is the upper surface 4a. In addition, the surface, of each of the light-transmissive members 6, opposite to the surface on the light-emitting element side is the upper surface 6a. The light-emitting elements 4 are placed on the lower surfaces of the respective light-transmissive members 6.
Step of Applying Mixture onto Light-Emitting Element

Subsequently, as illustrated in FIG. 6C, the mixture 50 is applied onto the light-transmissive member assembly so as to cover the light-emitting elements 4. During this application, it is desirable to vibrate the mixture 50 as in the first manufacturing method. In addition, also in the present manufacturing method, a protective film may be disposed on the surfaces of the electrodes 3 by atomic layer deposition before and/or after the application of the mixture 50 as in the first manufacturing method.

### Step of Forming Light-Reflective Member

Subsequently, the mixture 50 is cured by heating to form the light-reflective member 5 as in the first manufacturing method.

### Step of Exposing Electrodes

Subsequently, as illustrated in FIG. 6D, the cured light-reflective member 5 is ground to expose the lower surfaces 3a of the electrodes 3 of the light-emitting elements 4. Note that here, the surfaces of the electrodes 3 opposite to the surface proximate to the light-emitting element 4 are each the lower surface 3a. In this manner, the intermediate including the plurality of light-emitting elements 4, the plurality of light-transmissive members 6 disposed on the upper surfaces 4a of the respective light-emitting elements 4, and the light-reflective member 5 is formed.

### Step of Dicing

Subsequently, the light-emitting device 1 is obtained through dicing the intermediate by cutting the light-reflective member 5 along a predetermined cutting position CL, so as to include one of the light-emitting elements 4. The dicing is performed by using a blade, for example.

A manufacturing method for the light-emitting device 100 according to the second embodiment will be described below.

In the following description, the step of providing the light-emitting element, the step of providing the mixture, and the step of forming the light-reflective member by curing the mixture by heating are the same as those described above, and thus description of these steps will be omitted or simplified.

### Step of Providing Base

The base 35 is provided that includes the bottom portion 32 and the wall portion 33, which define the recessed portion. When the base material 30 of the base 35 is formed of a resin material, the bottom portion 32 and the wall portion 33 can be integrally formed by injection molding or the like, for example. When the base material 30 of the base 35 is formed of a ceramic material, the base 35 can be manufactured by either a so-called post-firing method or a so-called co-firing method. Whether the base material 30 of the base 35 is formed of a resin material or a ceramic material, the bottom portion 32 and the wall portion 33 can be formed separately and then bonded to each other using an adhesive or the like.

### Step of Disposing Light-Emitting Element

The light-emitting element 4 including the growth substrate 7 and the semiconductor layered body 2 is disposed on the bottom portion 32 of the base 35 in the recessed portion 31. The light-emitting element 4 is mounted by connecting the electrodes 3 to the wiring layer 41 via solder or the like.

The mixture is provided as in the first manufacturing method.

Here, in the present manufacturing method, by adjusting the fluidity (viscosity) of the mixture, it is possible to form, in a step of disposing the mixture, an inclined region R1 whose surface is inclined at a desired angle or curved in a desired shape from the wall portion 33 toward the light-emitting element 4. The fluidity (viscosity) of the mixture can be adjusted, for example, by adding and mixing a vaporizable solvent in the mixture.

### Step of Disposing Mixture

In the recessed portion 31, the mixture is disposed on the bottom portion 32 of the base 35. The mixture is spaced apart from the lateral surfaces 2a of the semiconductor layered body 2. The mixture is disposed so as to include a region whose height decreases from the wall portion 33 toward the light-emitting element 4.

The mixture is applied and disposed, for example, by a dispenser. For example, the mixture is applied simultaneously to the wall portion 33 and the bottom portion 32, or applied to the inner lateral surface 33a of the wall portion 33. In this way, the inclined region can be formed. In addition, by applying the mixture simultaneously to the wall portion 33 and the bottom portion 32, or applying the mixture to the inner lateral surface 33a of the wall portion 33, it is possible to dispose the mixture at a position spaced apart from the light-emitting element 4, and it is thus possible to inhibit the lateral surfaces 2a of the semiconductor layered body 2 from being covered with the mixture.

### Step of Forming Light-Reflective Member by Heating Mixture/Step of Heating

The light-reflective member 55 is formed by curing the mixture 50 by heating as in the first manufacturing method.

In the above-described manner, the light-emitting device 100 according to the second embodiment can be formed. Note that the step of disposing the light-emitting element may be performed before the step of disposing the mixture, or after the step of forming the light-reflective member by heating the mixture. In addition, the light-emitting devices 100 may be individually manufactured, or a plurality of the light-emitting devices 100 may be integrally formed and then diced. Specifically, an aggregate substrate including the bottom surface and a plurality of walls is provided, a light-emitting element and a mixture are disposed in each of a plurality of recessed portions formed by the bottom surface and the plurality of walls, the mixture is cured by heating, and the aggregate substrate is diced into individual light-emitting devices.

### Examples and Reference Examples

Examples and Reference Examples will be described below.

In Reference Example 1 and Examples 1 to 3, the light-reflective member was formed, changing the composition of the mixture when forming the light-reflective member from that in the light-emitting device 1 of the first embodiment, and the thermal resistance Rj-a of each of the light-reflective members was measured.

Table 1 shows raw materials of the mixture for forming the light-reflective member, ratios of the raw materials, and the thermal resistance Rj-a of the formed light-reflective member in Reference Example 1 and Examples 1 to 3.

TABLE 1

| | | KOH | | | | Rj-a |
|---|---|---|---|---|---|---|
| | SiO₂(g) | (mol/L) | BN(g) | TiO₂(g) | CaO(g) | (° C./W) |
| Reference | 1.5 | 1.9 | 2.5 | 1 | 0 | 37.1 |
| Example 1 | | | | | | |
| Example 1 | 1.5 | 1.9 | 2.35 | 1 | 0.15 | 36.5 |
| Example 2 | 1.5 | 1.9 | 2.2 | 1 | 0.3 | 36.2 |
| Example 3 | 1.5 | 1.9 | 2.05 | 1 | 0.45 | 36.1 |

Here, the mean particle diameter of silicon oxide (SiO₂) used for the raw material is 0.4 μm in median diameter. Further, the mean particle diameter of the light-reflective material powder formed of boron nitride (BN), which also functions as the aggregate, is 10 μm, and the average aspect ratio thereof is 20. The mean particle diameter of the light-reflective material powder formed of titanium oxide (TiO₂), which also functions as the light-scattering material, is 2.5 μm. The mean particle diameter of calcium oxide (CaO) used for the raw material is 15 μm.

The mixture was cured by heating the mixture 50 at 90° C. under a pressure of 1 MPa for 0.5 hours to temporarily cure the mixture, and then heating the mixture 50 at 200° C. under a pressure of 1 MPa for one hour.

In addition, the thermal resistances Rj-a were evaluated by performing a transient thermal resistance measurement using a heating method (dynamic method) for each of the light-emitting devices in which the light-reflective members of Reference Example 1 and Examples 1 to 3 were formed, respectively, and by comparing the measured thermal resistance values.

As shown in Table 1, it was confirmed that the thermal resistance can be reduced when the mixture contains calcium oxide (CaO).

Subsequently, using Example 3 as a reference, Reference Examples 2 and 3 were produced in which the content ratios of boron nitride and calcium oxide in the mixture were changed, and the light-reflective members after curing were evaluated.

Table 2 shows the ratio of the mixed powder in the mixture. The ratios of the mixed powder and potassium hydroxide in Reference Examples 2 and 3 are the same as those in Example 3, and the potassium hydroxide is not shown in Table 2. In addition, Table 2 also shows Example 3.

TABLE 2

| | | KOH | | | | CaO | |
|---|---|---|---|---|---|---|---|
| | SiO₂(g) | (mol/L) | BN(g) | TiO₂(g) | CaO(g) | (wt %) | Crack |
| Example 3 | 1.5 | 1.9 | 2.05 | 1 | 0.45 | 6.5 | No |
| Reference Example 2 | 1.5 | 1.9 | 1.75 | 1 | 0.75 | 10.7 | Yes |
| Reference Example 3 | 1.5 | 1.9 | 2.5 | 1 | 0.5 | 6.8 | Yes |

Here, CaO (wt. %) shown in Table 2 indicates the content ratio of alkaline earth oxides including CaO in the mixture. As shown in Table 2, no crack was observed in the cured light-reflective member in Example 3, whereas cracks were observed in the cured light-reflective members in Reference Examples 2 and 3. Thus, it is not preferable that the content ratio of the alkaline earth oxides in the mixture is too high. Therefore, the content ratio of the alkaline earth oxides in the mixture is preferably adjusted to 6.6 wt. % or less, for example.

The embodiments disclosed this time are illustrative in all respects and are not intended to be the basis of limiting interpretation.

What is claimed is:

1. A light-emitting device comprising:
a light-emitting element; and
a light-reflective member comprising an inorganic member and configured to reflect light emitted from the light-emitting element, wherein
the inorganic member contains silicon oxide, an alkali metal, and a hydroxide containing an alkaline earth metal.

2. The light-emitting device according to claim 1, wherein the alkali metal comprises potassium or sodium.

3. The light-emitting device according to claim 1, wherein the alkaline earth metal comprises at least one selected from the group consisting of calcium, magnesium, and beryllium.

4. The light-emitting device according to claim 1, wherein the alkali metal comprises potassium.

5. The light-emitting device according to claim 1, wherein the alkaline earth metal comprises calcium.

6. The light-emitting device according to claim 1, wherein the light-reflective member further comprises a light-reflective material containing at least one selected from the group consisting of boron nitride, titanium oxide, zirconium oxide, and aluminum oxide.

7. The light-emitting device according to claim 6, wherein the light-reflective material contains boron nitride.

8. The light-emitting device according to claim 1, wherein a content ratio, in the light-reflective member, of the hydroxide containing the alkaline earth metal is in a range of 0.1 wt. % to 8.7 wt. %.

9. The light-emitting device according to claim 1, wherein an open porosity of the light-reflective member is in a range of 20% to 40%.

10. An inorganic member comprising:
silicon oxide;
an alkali metal; and
a hydroxide containing an alkaline earth metal.

11. An inorganic member comprising:
silicon oxide;
an alkali metal;
an oxide containing an alkaline earth metal; and
water.

12. A method for manufacturing a light-emitting device, the method comprising:
providing a light-emitting element comprising a semiconductor structure;
providing a mixture by mixing silicon oxide powder, an oxide containing an alkaline earth metal, and an alkaline solution containing an alkali metal;
applying the mixture onto a region to be irradiated with light from the light-emitting element; and
forming a light-reflective member by curing the mixture by heating.

13. The method according to claim 12, wherein
in the providing of the mixture, a content ratio, in the mixture, of the oxide containing the alkaline earth metal is in a range of 0.1 wt. % to 6.6 wt. %.

14. The light-emitting device according to claim 1, wherein the hydroxide containing the alkaline earth metal is a crystal of Ca(OH)₂, a crystal of Mg(OH)₂, or a crystal of Be(OH)₂.

15. The inorganic member according to claim 10, wherein the alkali metal comprises potassium or sodium.

16. The inorganic member according to claim 10, wherein the alkaline earth metal comprises at least one selected from the group consisting of calcium, magnesium, and beryllium.

17. The inorganic member according to claim 11, wherein the alkali metal comprises potassium or sodium.

18. The inorganic member according to claim 11, wherein the alkaline earth metal comprises at least one selected from the group consisting of calcium, magnesium, and beryllium.

19. The method according to claim 12, wherein the alkali metal comprises potassium or sodium.

20. The method according to claim 12, wherein in the providing of the mixture, a mean particle diameter of the silicon oxide powder is in a range of 0.1 μm to 10 μm.
